(19) United States
(12) Patent Application Publication
(10) Pub. No.: US 2008/0054979 A1
(43) Pub. Date: Mar. 6, 2008

(54) LEVEL SHIFTING CIRCUIT, DRIVING DEVICE, LED PRINT HEAD, AND IMAGE FORMING APPARATUS

(75) Inventor: Akira NAGUMO, Tokyo (JP)

Correspondence Address: PANITCH SCHWARZE BELISARIO & NADEL LLP, ONE COMMERCE SQUARE, 2005 MARKET STREET, SUITE 2200, PHILADELPHIA, PA, 19103, US

(73) Assignee: OKI DATA CORPORATION, Tokyo (JP)

(21) Appl. No.: 11/843,684

(22) Filed: Aug. 23, 2007

(30) Foreign Application Priority Data
Aug. 31, 2006 (JP) 2006-235444

(51) Int. Cl. H03K 19/0185; H03L 5/00

(52) U.S. Cl. 327/309; 327/333

(57) ABSTRACT

A level shifting circuit converts an input signal that varies between ground and a first voltage to a shifted signal that varies between ground and a second voltage higher than the first voltage. The level shifting circuit has two branches, in each of which a p-channel transistor and two n-channel transistors are connected in series between the second voltage and ground. When the two n-channel transistors in each branch are turned off, a clamping circuit clamps the node between them to the first voltage level, so that neither n-channel transistor has to withstand the full difference between the second voltage and ground. The level shifting circuit can accordingly be fabricated with transistors of small size, reducing the cost of driving circuits, light-emitting-diode print heads, and image forming apparatus in which the level shifting circuit is used.

### BACKGROUND OF THE INVENTION

1. Field of the Invention

The present invention relates to a level shifting circuit, a driving device using the level shifting circuit, and a light-emitting diode (LED) print head and image forming apparatus incorporating the driving device.

2. Description of the Related Art

There are various types of conventional image forming apparatus, including image display apparatus and image recording apparatus such as printers, that employ semiconductor chips in which arrays of LEDs or other light-emitting elements are formed. These light-emitting element array chips are driven by integrated circuit (IC) chips in which driving circuits are formed, the light-emitting element array chips and driver ICs generally being mounted side by side. To meet the growing demand for high resolution in image forming apparatus, the density of the arrays and their driving circuits has increased markedly.

Driver ICs in particular are now manufactured by semiconductor fabrication processes with very small feature sizes, and their power supply voltages have been reduced accordingly, but there has been little or no corresponding change in the voltages needed to drive the light-emitting elements (the driven elements). As a result, most parts of the driver ICs, including their logic circuitry, are fabricated by a fine-featured process that creates circuit elements such as metal-oxide-semiconductor (MOS) field-effect transistors (FETs) with low breakdown voltages, and the output stages that drive the light-emitting elements are fabricated so that their circuit elements have a higher breakdown voltage, as described, for example, in Japanese Patent Application Publication No. 2005-311712 (pages 9-10 and FIG. 1).

A problem when low-voltage logic and higher-voltage driving circuits are combined in the same IC chip is that the fine-featured fabrication process used to fabricate the logic circuits cannot be used to fabricate the high-voltage driving circuits; separate processes must be used, so the fabrication process for the entire chip becomes very lengthy, involving many different steps. Another problem is that high-voltage MOS FETs must have a greater gate length than the MOS FETs in the logic circuits, so they take up an inordinate amount of space, and prevent the size and hence the cost of the chip from being reduced.

### SUMMARY OF THE INVENTION

An object of the present invention is to provide a level shifting circuit and driving device that permit the use of a fine-featured semiconductor fabrication process.

Another object of the invention is to provide an LED print head and an image forming apparatus using this shifting circuit and driving device.

The invention provides a level shifting circuit for converting an input signal and an inverted input signal that vary in a complementary manner between a reference voltage and a first voltage to a shifted signal that varies between the reference voltage and a second voltage. The first and second voltages are typically power supply voltages, the second voltage being higher than the first voltage. The reference voltage is typically a ground voltage.

The level shifting circuit has a first node, a second node, a third node, and a fourth node. The shifted signal is output from the fourth node.

The level shifting circuit includes a clamping circuit that clamps the second node at the first voltage level when the input signal is at the first voltage level and clamps the first node at the first voltage level when the input signal is at the reference voltage level.

The level shifting circuit also includes:

a first transistor of a first conductive type for feeding the second voltage to the third node, a third transistor of a second conductive type for feeding the reference voltage to the first node, and a fifth transistor of the second conductive type inserted in series between the first and third nodes; and

a second transistor of the first conductive type for feeding the second voltage to the fourth node, a fourth transistor of the second conductive type for feeding the reference voltage to the second node, and a sixth transistor of the second conductive type inserted in series between the second and fourth nodes.

The first and second transistors are cross-coupled. The third and fifth transistors receive the input signal at their control terminals. The fourth and sixth transistors receive the inverted control signal at their control terminals. When the input signal is at the reference voltage level, the first, fourth, and sixth transistors are turned on, the second, third, and fifth transistors are turned off, and the output signal is at the reference voltage level. When the input signal is at the first voltage level, the second, third, and fifth transistors are turned on, the first, fourth, and sixth transistors are turned off, and the output signal is at the second voltage level.

Because of the clamping circuit, when the third, fourth, fifth, and sixth transistors are turned off, they only have to withstand the voltage difference between the reference voltage and the first voltage, or between the first voltage and the second voltage, and do not have to withstand the larger voltage difference between the reference voltage and the second voltage. Consequently, these transistors do not require special structures, and the entire level shifting circuit can be fabricated with transistors of small size.

The invention also provides a driving device for individually driving a plurality of driven elements. The driving device includes a control voltage generating circuit, a plurality of pre-buffers, and a plurality of driving transistors. The control voltage generating circuit generates a control voltage. Each pre-buffer includes a first level shifting circuit that receives an input signal and outputs a shifted signal as described above, and a second level shifting circuit that converts the shifted signal output to a reshifted signal that varies between the control voltage and the second voltage. The reshifted signals output from the pre-buffers control respective driving transistors that supply driving current to the driven elements.

Like the first level-shifting circuit, the second level-shifting circuit does not have to withstand the full voltage difference between the reference voltage and the second voltage. The pre-buffer circuits can accordingly be fabricated by a fine-featured process and the driving device can be small in size, hence relatively inexpensive.

The invention also provides an LED print head including the above type of driving device and an LED array, and an image-forming apparatus including the LED print head.

### BRIEF DESCRIPTION OF THE DRAWINGS

In the attached drawings:

FIG. 1 is a simplified block diagram of an image-forming apparatus using an LED print head according to the present invention;

FIG. 2 is a partial circuit diagram of the LED print head in FIG. 1;

FIG. 3 is a timing waveform diagram illustrating the operation of the LED print head in FIG. 2;

FIG. 4 is a circuit diagram illustrating a pre-buffer and its associated circuits in the LED print head in FIG. 2;

FIG. 5 is a circuit diagram illustrating a level shifting circuit according to a first embodiment of the invention;

FIG. 6 is a voltage waveform diagram illustrating the operation of the level shifting circuit in FIG. 5;

FIG. 7A is a simplified block diagram illustrating the level shifting of the data signal in the pre-buffer in FIG. 4;

FIG. 7B illustrates the levels of the output signals in FIG. 7A;

FIG. 8 is a more detailed circuit diagram illustrating the level shifting circuits in the pre-buffer in FIG. 4;

FIG. 9 is a circuit diagram of an LED driving circuit in a driving device according to a second embodiment of the invention;

FIG. 10 is a voltage waveform diagram illustrating the operation of the LED driving circuit in FIG. 9;

FIG. 11 is a sectional drawing of an LED print head according to a third embodiment of the invention;

FIG. 12 is a plan view of the LED unit in FIG. 11; and

FIG. 13 is a sectional view of an image forming apparatus according to a fourth embodiment of the invention.

### DETAILED DESCRIPTION OF THE INVENTION

Embodiments of the invention will now be described with reference to the attached drawings, in which like elements are indicated by like reference characters.

The following nomenclature will be employed: IC will denote a monolithic integrated circuit; ‘1’ will denote the high logic level of a logic signal; ‘0’ will denote the low logic level of a logic signal; the suffix ‘−N’ will denote negative logic; p-channel and n-channel MOS FETs will be referred to as PMOS and NMOS transistors, respectively.

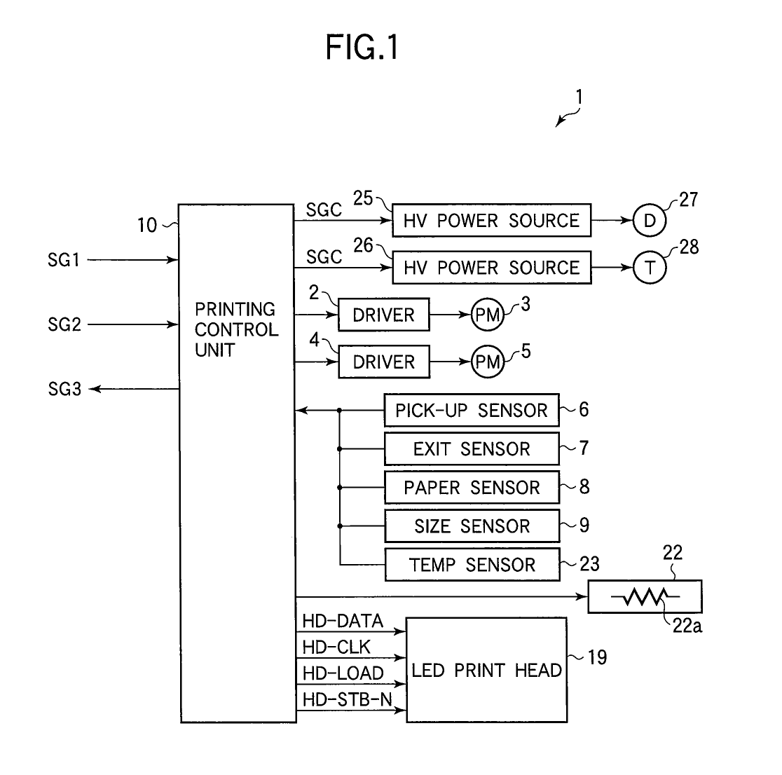

FIG. 1 illustrates the control system of an electrophotographic printer employing an LED print head according to the present invention. The control system 1 encompasses a printing control unit 10, a pair of motor drivers 2, 4, a develop-transfer process motor (PM) 3, a paper feed motor 5, a pick-up sensor 6, an exit sensor 7, a paper sensor 8, a size sensor 9, a fuser temperature (TEMP) sensor 23, a fuser 22, the LED print head 19, a high-voltage (HV) charging power source 25, a high-voltage transfer power source 26, a developing unit (D) 27, and a transfer unit (T) 28.

The electrophotographic printer in FIG. 1 uses the LED print head 19 to form a latent electrostatic image on the surface of a charged photosensitive drum by selective illumination of the surface responsive to printing information, develops the image by applying toner to form a toner image, transfers the toner image to paper, and fuses the toner image onto the paper. This process can be described as follows.

The printing control unit 10 in FIG. 1 comprises a microprocessor, a read only memory (ROM), a random access memory (RAM), input and output ports, timers, and other components, and is disposed inside the printing unit. Upon receiving a control signal SG1, a video signal SG2 (one-dimensionally sequenced dot-mapped data), and other signals from a host controller (not shown), the printing control unit 10 controls a sequence of operations for printing the dot-mapped data. When the printing control unit 10 receives a printing command given by the control signal SG1, first it detects, by using the fuser temperature sensor 23, whether the fuser 22 is within the usable temperature range. If the fuser 22 is not within the usable temperature range, current is fed to a heater 22a in the fuser 22 to raise the temperature of the fuser 22.

Next, the control system 1 commands the motor driver 2 to turn the develop-transfer process motor 3, activates a charge signal SGC to turn on the high-voltage charging power source 25, and thereby charges the developing unit 27. In addition, the paper sensor 8 is checked to confirm that paper is present in a cassette (not shown), and the size sensor 9 is checked to determine the size of the paper. If paper is present, the motor driver 4 drives the paper feed motor 5 according to the size of the paper, first in one direction to transport the paper to a starting position sensed by the pick-up sensor 6, then in the opposite direction to transport the paper into the printing mechanism.

When the paper is in position for printing, the printing control unit 10 sends the host controller a timing signal SG3 (including a main scanning synchronization signal and a sub-scanning synchronization signal). The host controller responds by sending the dot data for one page in the video signal SG2. The printing control unit 10 sends the corresponding print data (HD-DATA) to the LED print head 19. The LED print head 19 includes a linear array of LEDs for printing respective dots (also referred to as picture elements or pixels).

After receiving data for one line of dots in the video signal SG2 and sending the data to the LED print head 19, the printing control unit 10 sends the LED print head 19 a latch signal (HD-LOAD), causing the LED print head 19 to store the print data (HD-DATA). The print data stored in the LED print head 19 can then be printed while the printing control unit 10 is receiving the next print data from the host controller in the video signal SG2.

A clock signal HD-CLK and a strobe signal HD-STB-N are input to the LED print head 19. The clock signal is used to synchronize the transfer of print data (HD-DATA) to the LED print head 19.

The video signal SG2 is transmitted and received one printing line at a time. The LED print head 19 emits light according to the print data when the strobe signal (HD-STB-N) is driven to the low logic level and forms a latent image of dots with a relatively positive electric potential on the negatively charged photosensitive drum (not shown). In the developing unit 27, negatively charged toner is electrically attracted to the dots, forming a toner image. The toner image is then transported to the transfer unit 28.

The printing control unit 10 activates the high-voltage transfer power source 26 by sending it a transfer signal SG4, and the toner image is transferred to a sheet of paper passing between the photosensitive drum and the transfer unit 28. The sheet of paper carrying the transferred toner image is transported to the fuser 22, where the toner image is fused onto the paper by heat generated by the heater 22a. Finally, the sheet of paper carrying the fused toner image is transported out of the printing mechanism, passing the exit sensor 7, and is ejected from the printer.

The printing control unit 10 controls the high-voltage transfer power source 26 according to the information detected by the pick-up sensor 6 and size sensor 9 so that the voltage from the high transfer voltage is applied to the transfer unit 28 only while paper is passing through the transfer unit 28. When the paper passes the exit sensor 7, the printing control unit 10 stops the supply of voltage from the high-voltage charging power source 25 to the developing unit 27, and halts the develop-transfer process motor 3. The above operations are repeated to print a series of pages.

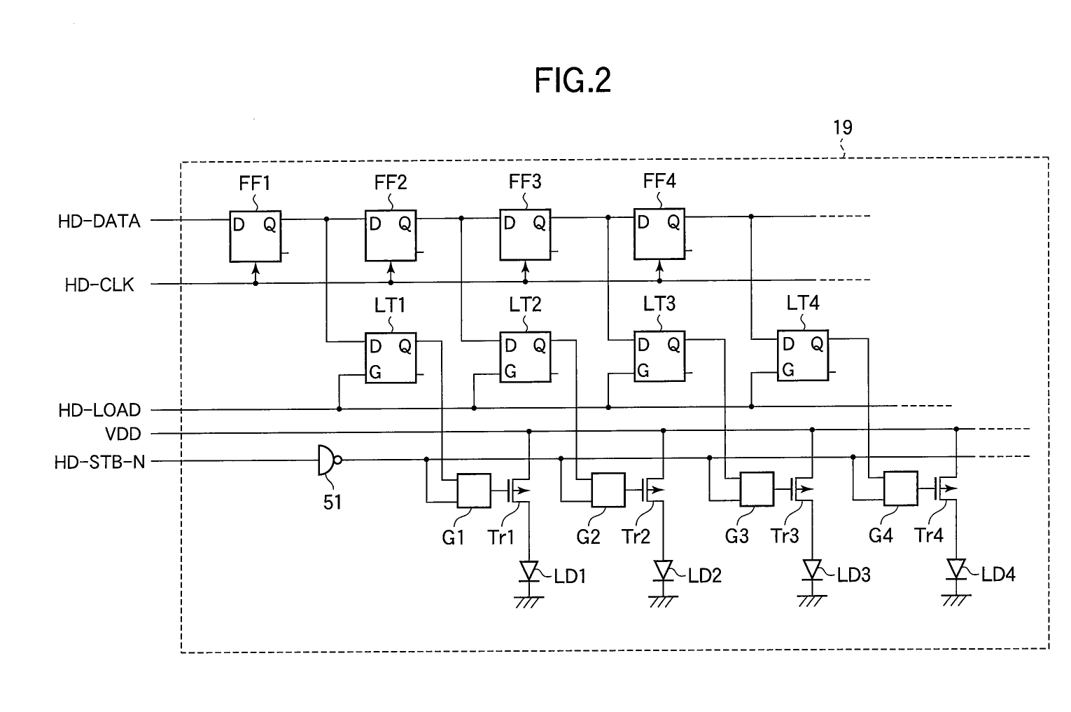

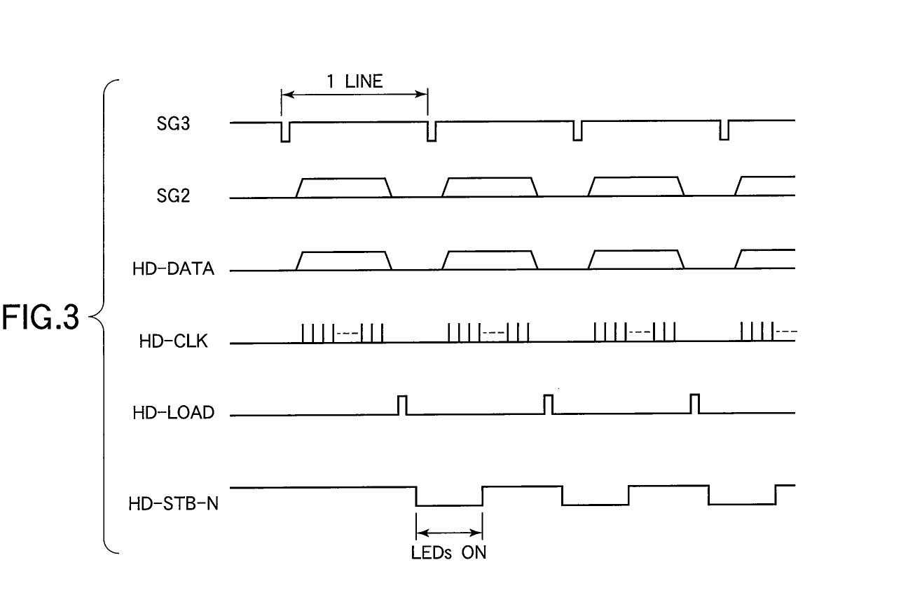

FIG. 2 is a schematic circuit diagram illustrating the internal structure of the LED print head 19. FIG. 3 is a timing waveform diagram illustrating the operation of the LED print head 19.

An LED print head capable of printing on A4-size paper at a resolution of 600 dots per inch will be taken as an example. The light-emitting unit in this LED print head forms a line of 4992 dots and is configured from twenty-six LED array chips, each chip including 192 light-emitting diodes.

The twenty-six LED array chips are disposed end to end on a printed wiring board (not shown) in the light-emitting unit, facing respective driver ICs, which are also mounted on the printed wiring board. Each driver IC has 192 driving terminals. Each driving terminal is connected to the anode of a light-emitting diode in the LED array by a bonding wire. Each driver IC includes a shift register comprising 192 flip-flop elements for transferring print data. The data shifted out from the shift register are shifted into the shift register in the next driver IC; that is, the shift registers in the driver ICs are cascaded to form a single shift register.

FIG. 2 shows the first four of the 26×192 light-emitting diodes LD1 to LD4992 and their associated driving circuits, without indicating the boundaries between the LED array and driver IC chips. Light-emitting diodes LD5 to LD4992 and the corresponding driving circuits are omitted.

Referring to FIGS. 2 and 3, the print data HD-DATA and clock signal HD-CLK are used to shift bit data for 4992 dots into the shift register comprising flip-flops FF1, FF2, . . . , FF4992. The latch signal HD-LOAD causes latches LT1, LT2, . . . , LT4992 to latch the bit data. The strobe signal HD-STB-N activates a circuit comprising an inverter 51, pre-buffers G1, G2, . . . , G4992, and switching elements Tr1, Tr2, . . . , Tr4992 that drive the linear array of light-emitting elements LD1, LD2, . . . , LD4992 according to the latched bit data. The switching elements are PMOS transistors; the light-emitting elements are LEDs.

The flip-flops FF1, . . . and latches LT1, . . . in the driver ICs operate on a first power supply voltage VD (not explicitly shown in FIG. 2). The light-emitting elements LD1, . . . are driven from a second power supply voltage VDD approximately twice as high as the first supply voltage VD.

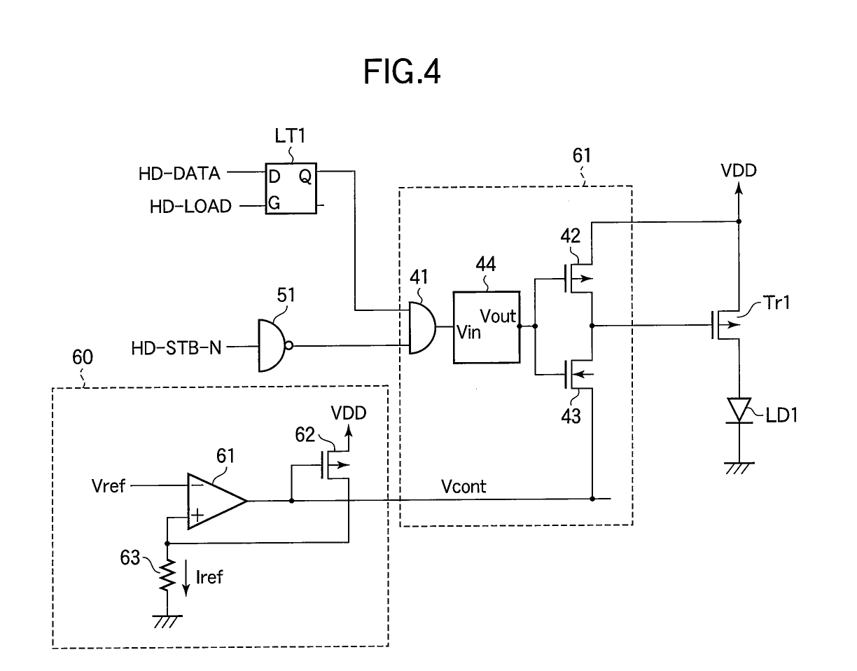

The pre-buffers G1, G2, . . . , G4992 will now be described in further detail. Since all the pre-buffers G1, G2, . . . , G4992 have the same configuration, the pre-buffer G1 corresponding to the first dot will be described. FIG. 4 shows this pre-buffer G1 along with its peripheral circuits including latch LT1, inverter 51, LED driving transistor Tr1, light-emitting diode LD1, and a control voltage generator 60. Each driver IC chip has one control voltage generator 60 and one inverter 51, the outputs of which are provided to all pre-buffers in the chip. The control voltage generator 60 was not shown in FIG. 2.

Pre-buffer G1 comprises an AND gate 41, a level converter 44, a PMOS transistor 42, and an NMOS transistor 43. The output of the AND gate 41 is connected through the level converter 44 to the gate terminals of the PMOS transistor 42 and NMOS transistor 43. The PMOS transistor 42 has a source terminal connected to the second power supply VDD and a drain terminal connected to the drain terminal of the NMOS transistor 43. The NMOS transistor 43 has a source terminal connected to the output of the control voltage generator 60 described later. As described later, the level converter 44 controls the PMOS transistor 42 and NMOS transistor 43 so that they turn on and off in a complementary fashion according to the ‘0’ or ‘1’ value of the output of the AND gate 41.

Latch LT1 receives the latch signal HD-LOAD, latches the data corresponding to the first dot of the print data HD-DATA, and outputs the latched data to one of the input terminals of the AND gate 41. Inverter 51 inverts the strobe signal HD-STB-N and outputs the inverted signal to the other one of the terminals of the AND gate 41. The LED driving transistor Tr1 has a gate terminal connected to the drain terminals of PMOS transistor 42 and NMOS transistor 43, a source terminal connected to the second power supply VDD, and a drain terminal connected to the anode of the light-emitting diode LD1. The cathode of the light-emitting diode LD1 is connected to ground.

The control voltage generator 60 includes an operational amplifier 61, a PMOS transistor 62, and a resistor 63. The operational amplifier 61 has an inverting input terminal receiving a reference voltage Vref supplied from a reference voltage generator (not shown), a non-inverting input terminal connected to ground through the resistor 63 and to the drain terminal of the PMOS transistor 62, and an output terminal connected to the gate terminal of PMOS transistor 62 and to the source terminal of the NMOS transistor 43 in the pre-buffer G1. The output of the operational amplifier 61, which is the output voltage Vcont of the control voltage generator 60, is similarly supplied to the other pre-buffers in the same driver IC chip.

The control voltage generator 60 is thus configured as a feedback control circuit, in which the reference current Iref conducted by the resistor 63 and PMOS transistor 62 is determined by the reference voltage Vref and the resistor value Rref of the resistor 63 despite variations in the second supply voltage VDD. The gate length of PMOS transistor 62 is equal to the gate length of the LED driving transistor Tr1. When the strobe signal HD-STRB-N is driven to the ‘0’ level, if the output from latch LT1 is at the logic ‘1’ level, NMOS transistor 43 in the pre-buffer G1 is turned on and the gate voltage of the LED driving transistor Tr1 becomes equal to the control voltage Vcont, which creates a current mirror relationship between PMOS transistor 62 and the LED driving transistor Tr1, both of which operate in their saturation region.

The LED driving transistors Tr1 to Tr4992 all have identical gate lengths, so that all the LED driving transistors Tr1 to Tr192 in the same driver IC chip are in a current mirror relationship with the same PMOS transistor 62. Accordingly, the driving current values of the light-emitting diodes LD1 to LD192 can all be adjusted together, since they are proportional to the reference current Iref.

As described above, in the LED print head 19 including the twenty-six LED arrays each having 192 LED elements, it becomes possible to adjust the driving currents on a per-LED-array basis. Therefore, the LED print head 19 can be configured so as to adjust variations in the amount of emitted light caused by differences between the LED array chips, such as variability in their specified opto-electrical characteristics.

Next, conditions will be considered under which PMOS transistor 62 and LED driving transistor Tr1 (also a PMOS transistor) can operate in their saturation region.

If the drain-to-source voltage and gate-to-source voltage are denoted Vds and Vgs, respectively, the following relationship must be satisfied.

Vds>Vgs−Vt (1)

where, Vt denotes the MOS transistor threshold voltage.

The drain-to-source voltage Vds of PMOS transistor Tr1 is given by the following equation.

Vds=VDD−Vf (2)

In equation (2), Vf denotes the forward voltage of an LED element. The value of Vf is about 1.8 V for a red LED having an aluminum gallium arsenide (AlGaAs) substrate and about 3.6 V for a blue LED having a gallium nitride (GaN) substrate.

By way of example, if the threshold voltage Vt is 0.6 V and the gate-source voltage Vgs is 2.2 V, then the drain-source voltage Vds must meet the following condition:

Vds>Vgs−Vt=2.2−0.6=1.6 V

If a red LED is used, a 1.6-V drain-source voltage requires a power supply voltage VDD exceeding 3.4 V (VDD=Vds+Vf>1.6+1.8=3.4 V). This is higher than the typical supply voltage of 3.3 V used in complementary MOS semiconductor integrated circuits manufactured using a 0.35-micrometer fabrication process. Therefore, a level shifter is required as described later.

The gate-source voltage of 2.2 V assumed in the above example is the voltage difference between the power supply VDD and the control voltage Vcont. The control voltage Vcont can therefore be calculated from the power supply VDD and the gate-source voltage. For a power supply voltage VDD of 5 V, a control voltage Vcont of 2.8 V is obtained as follows.

$$\begin{matrix}V cont = V D D - V g s \\ = 5 - 2.2 = 2.8 V\end{matrix} \qquad ( 3 )$$

Substituting equation (2) into equation (1) gives the following relationship.

VDD−Vf>Vgs−Vt (4)

Transposing the terms Vf and Vgs yields the following equation.

VDD−Vgs>Vf−Vt (5)

From equations (3) and (5), the following relationship is obtained.

Vcont>Vf−Vt

Accordingly, when Vf=1.8 V and Vt=0.6 V, for example, the condition Vcont>1.8−0.6=1.2 V is obtained. This indicates that setting the control voltage Vcont to 1.2 V or more enables PMOS transistor 62 and LED drive transistor Tr1 to operate in their saturation region.

### First Embodiment

The first embodiment is a level shifting circuit that can be used in the level converter 44 in FIG. 4.

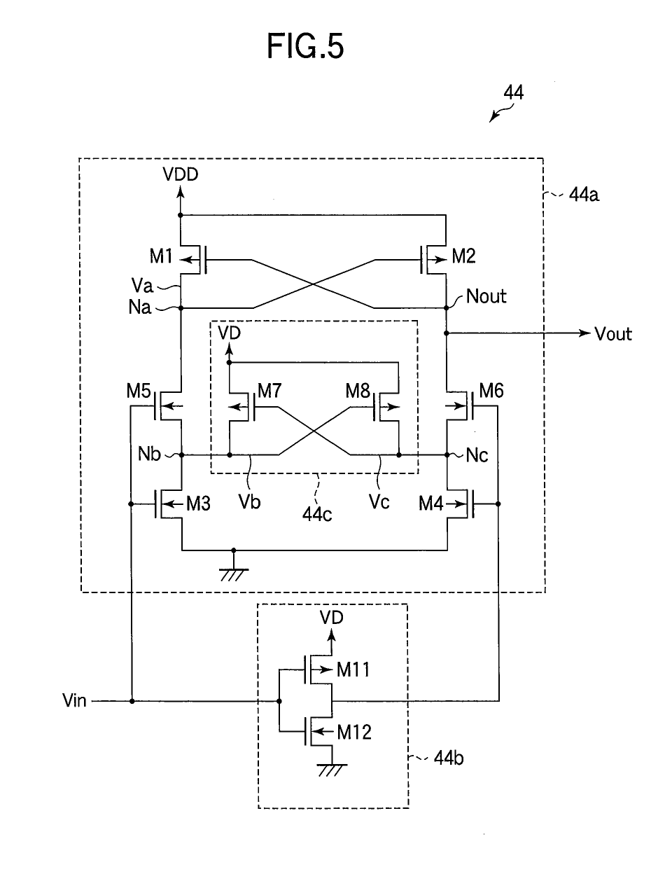

Referring to FIG. 5, the level shifting circuit 44a according to the first embodiment forms one part of the level converter 44, the other part being a level inverting circuit 44b. The level shifting circuit 44a includes a clamping circuit 44c connected to a first node Nb and a second node Nc. Reference characters M1, M2, M7, M8, and M11 indicate PMOS transistors; reference characters M3 to M6 and M12 indicate NMOS transistors.

PMOS transistor M1 has a source terminal connected to the second power supply voltage VDD (more precisely, to a power supply terminal that supplies the second supply voltage VDD), a drain terminal connected to the drain terminal of NMOS transistor M5 at a third node Na, and a gate terminal connected to the drain terminals of PMOS transistor M2 and NMOS transistor M6 at a fourth node Nout from which the shifted output signal Vout of the level shifting circuit is taken. PMOS transistor M2 has a gate terminal connected to the drain terminal of PMOS transistor M1 and NMOS transistor M5 at the third node Nb, a drain terminal connected to the drain terminal of NMOS transistor M6 at the output node Nout, and a source terminal connected to VDD.

NMOS transistor M3 has a source terminal connected to ground and a gate terminal connected to the input terminal of the level converter 44 to receive the input signal Vin. NMOS transistor M4 has a source terminal connected to ground and a gate terminal connected the output terminal of the level inverting circuit 44b to receive an inverted version of the input signal Vin. NMOS transistor M5 has a gate terminal connected to the input terminal of the level converter 44 to receive the input signal Vin, a source terminal connected to the drain terminal of NMOS transistor M3 at the first node Nb, and a drain terminal connected to the drain terminal of PMOS transistor M1 at the third node Na. NMOS transistor M6 has a gate terminal connected the output terminal of the level inverting circuit 44b to receive the inverted input signal, a source terminal connected to the drain terminal of NMOS transistor M4 at the second node Nc, and a drain terminal connected to the drain terminal of PMOS transistor M2 at the output node Nout.

PMOS transistor M7 has a gate terminal connected to the drain terminal of PMOS transistor M8, a drain terminal connected to the drain terminal of NMOS transistor M3 at the first node Nb, and a source terminal connected to the first supply voltage VD (more precisely, to a power supply terminal that supplies the first supply voltage VD). PMOS transistor M8 has a gate terminal connected to the drain terminal of PMOS transistor M7, a drain terminal connected to the drain terminal of NMOS transistor M4 at the second node Nc, and a source terminal connected to VD.

PMOS transistor M11 has a gate terminal connected to the input terminal of the level converter 44 to receive the input signal Vin, a drain terminal connected to the drain terminal of NMOS transistor M12, and a source terminal connected to the first power supply VD. NMOS transistor M12 has a gate terminal connected to the input terminal of the level converter 44 to receive the input signal Vin, a drain terminal connected to the drain terminal of PMOS transistor M11, and a source terminal connected to ground. PMOS transistor M11 and NMOS transistor M12 constitute the level inverting circuit 44b and their common drain terminal is the output terminal of the level inverting circuit 44b, from which the inverted input signal is output.

The level shifting circuit 44a and level inverting circuit 44b receive the same input signal Vin. The drain voltage of PMOS transistor M1 is denoted Va, the drain voltage of PMOS transistors M7 is denoted Vb, and the drain voltage of PMOS transistor M8 is denoted Vc.

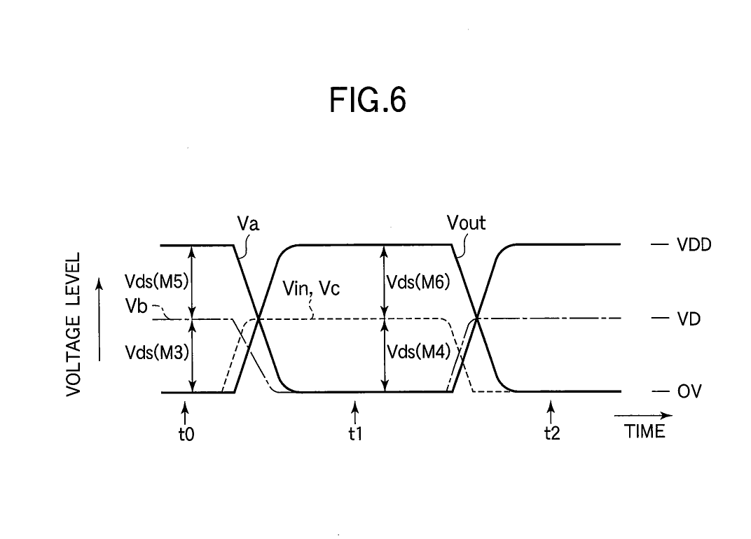

The operation of the level converter 44 will be described with reference to the voltage waveform diagram in FIG. 6.

First, when the input signal Vin is at the low logic level as shown at time t0, the NMOS transistors M3, M5 that receive the input signal Vin directly at their gate terminals are turned off and the NMOS transistors M4, M6 that receive the inverted input signal from the level inverting circuit 44b at their gate terminals are turned on. The turned-on NMOS transistors M4, M6 pull the gate potential of PMOS transistor M1 down to the ground level. PMOS transistor M1 accordingly turns on and pulls the gate potential of PMOS transistor M2 up to the VDD level, causing PMOS transistor M2 to turn off. The output signal Vout is at the ground voltage level (0 V).

Similarly, in the clamping circuit 44c, the gate potential of PMOS transistor M7 is pulled down by NMOS transistor M4 to the ground level, so PMOS transistor M7 turns on and pulls the gate potential of PMOS transistor M8 up to the VD level, causing PMOS transistor M8 to turn off.

The source-drain voltages Vds(M4) and Vds(M6) of NMOS transistors M4 and M6 are 0 V. Further, since the voltage Vb at the drain terminal of NMOS transistor M3 and the source terminal of NMOS transistor M5 is equal to the first supply voltage VD, although the voltage Va at the drain terminal of NMOS transistor M5 is the second supply voltage VDD, the source-drain voltages Vds(M3) and Vds(M5) of NMOS transistors M3 and M5 are both approximately equal to one-half of the second supply voltage VDD (approximately equal to the first supply voltage VD).

When the input signal Vin goes to the high logic level at time t1, the on and off states of MOS transistors M1 to M8 are all reversed. Accordingly, the output signal Vout becomes equal to second supply voltage VDD, the source-drain voltages Vds(M3) and Vds(M5) of NMOS transistors M3 and M5 are 0 V, and the source-drain voltages Vds(M4) and Vds(M6) of NMOS transistors M and M6 are approximately equal to one-half of the second supply voltage VDD (approximately equal to the first supply voltage VD).

Although the output signal Vout swings between ground level and the second supply voltage VDD, the source-drain voltages of NMOS transistors M3 to M6 never exceed a value approximately equal to half of VDD (approximately equal to the first supply voltage VD), regardless of whether the input signal Vin is high or low.

With the decreasing channel lengths of transistors formed by fine-featured semiconductor fabrication processes, hot-carrier degradation is becoming problematic, especially in NMOS transistors. In particular, when transistors with short channels are used in integrated circuits with the decreased feature sizes produced by current semiconductor fabrication processes, hot carriers occur even at a supply voltage of about 5 V. The hot carriers occur because electrons flowing from the source region to the drain region are accelerated by a strong electric field in the vicinity of the drain. The accelerated electrons have enough energy to ionize channel or drain atoms with which they collide, and such collisions generate a large number of electron-hole pairs, producing excessive drain current. The hot electrons may also be injected into the oxide film of the transistor, altering the threshold voltage of the transistor and reducing its transconductance.

The most effective way to solve this problem is to employ a structure such as an offset gate structure that mitigates the electric field in the drain edge region. The offset gate structure, however, is not always ideal from the point of view of operating speed, because it causes the on-current to decrease. There is also has a problem of high cost because the offset gate structure occupies a relatively large area on the chip.

With the level shift circuit of the first embodiment, the source-drain voltages of NMOS transistors M3 to M6 are limited to a voltage approximately equal to half the output voltage swing VDD. This eliminates the need to employ a special structure for these NMOS transistors, so the sizes of these transistors can be reduced down to the fabrication limit of a fine-featured semiconductor fabrication process, thereby enabling the cost of the driver IC to be reduced by a reduction of its chip size. Since these transistors are fabricated in the same way as other NMOS transistors, no extra process steps are necessary. The occurrence of hot carriers can also be prevented without sacrificing operating speed, thereby obtaining the effects of high-voltage output and high reliability at no cost in performance.

### Second Embodiment

The second embodiment is a driver IC having pre-buffers with the circuit structure shown in FIG. 4, including the level converter 44 shown in FIG. 5.

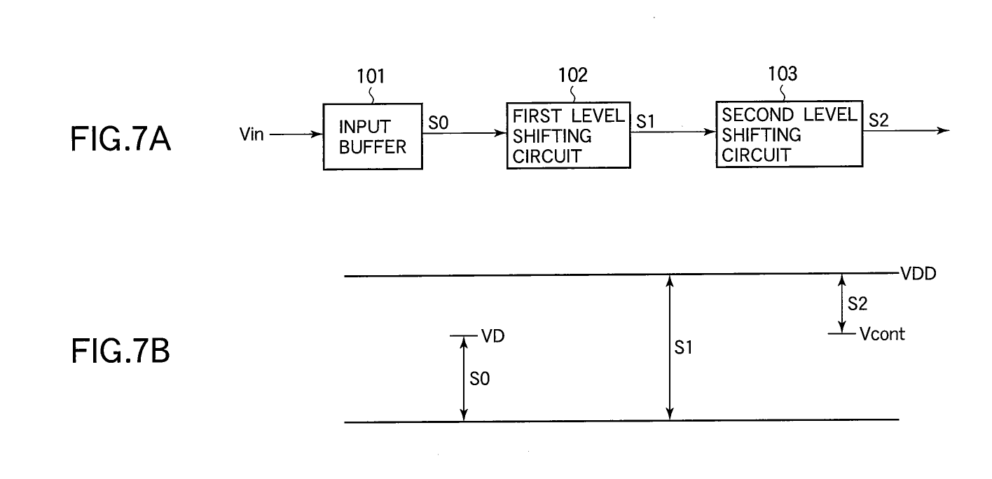

Referring to FIG. 7A, pre-buffer G1 can be regarded as comprising an input buffer 101 that receives the input signal Vin and outputs a signal S0, a first level shifting circuit 102 that receives signal S0 and outputs a signal S1, and a second level shifting circuit 103 that receives signal S1 and outputs a signal S2. The levels of the respective output signals S0, S1, S2 are illustrated schematically in FIG. 7B: output signal S0 swings between ground level (0 V) and the first supply voltage VD; output signal S1 swings between ground level (0 V) and the second supply voltage VDD; output signal S2 swings between the control voltage Vcont and the second supply voltage VDD.

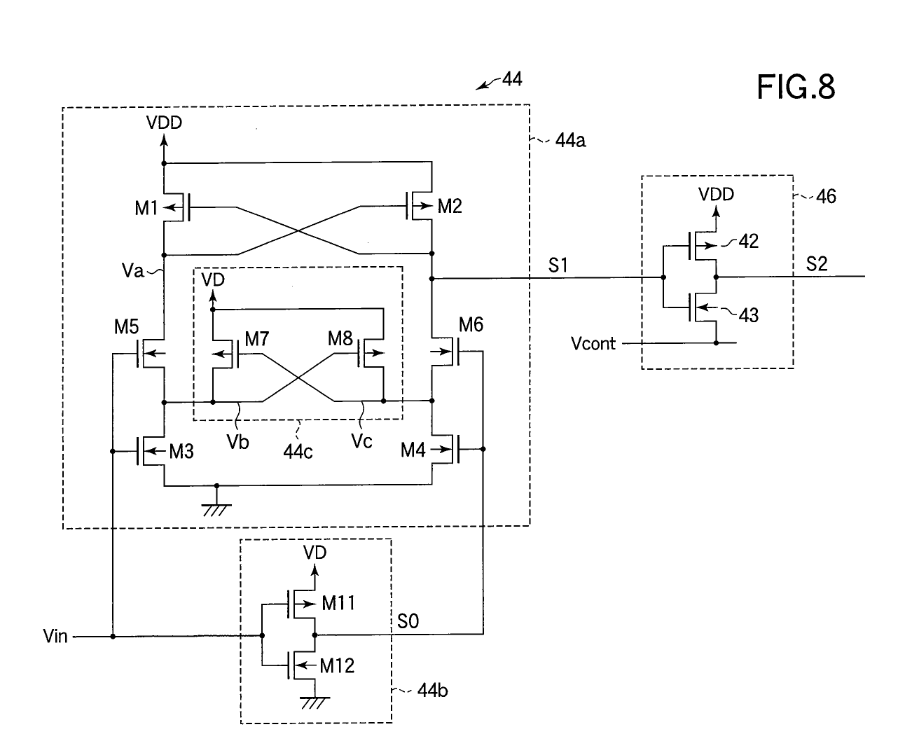

FIG. 8 relates the simplified block diagram in FIG. 7A to the circuitry shown in FIGS. 4 and 5. The level inverting circuit 44b in FIG. 5 is seen to correspond to the input buffer 101 in FIG. 7A; the level shifting circuit 44a in FIG. 5 corresponds to the first level shifting circuit 102; and a level shifting inverter 46 comprising PMOS transistor 42 and NMOS transistor 43 in FIG. 4 corresponds to the second level shifting circuit 103.

In the level shifting inverter 46, PMOS transistor 42 has a source terminal connected to VDD and a drain terminal connected to the drain terminal of NMOS transistor 43, while the source terminal of NMOS transistor 43 receives the control voltage Vcont as described above. The gate terminals of PMOS transistor 42 and NMOS transistor 43 receive the output signal S1 of first level shifting circuit. The interconnected drain terminals of PMOS transistor 42 and NMOS transistor 43 produce the output signal S2 of the level shifting inverter 46.

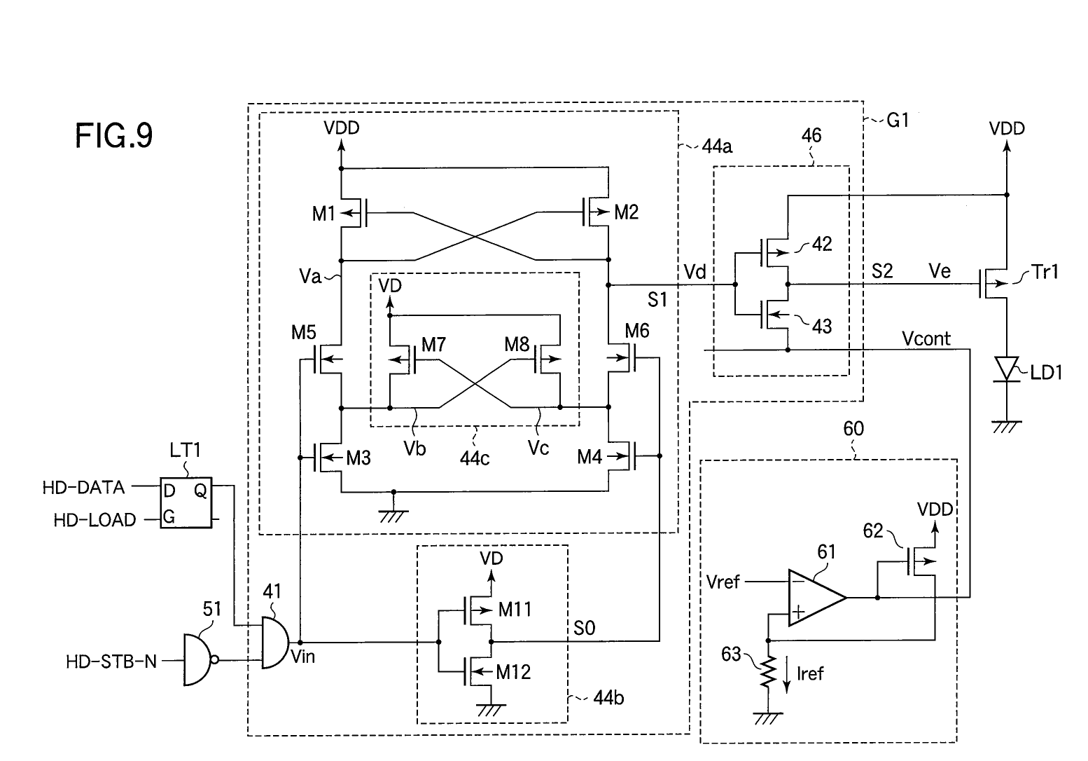

FIG. 9 expands the circuit diagram in FIG. 8 to include other elements of an LED driver IC according to the second embodiment of the invention.

As in FIG. 4, the LED driving circuit in FIG. 9 comprises the pre-buffer G1 shown in FIG. 2 and its peripheral circuits. The pre-buffer G1 includes the level shifting circuit 44a, level inverting circuit 44b, and level shifting inverter 46 shown in FIG. 8 and the AND gate 41 shown in FIG. 4. The other pre-buffers G1, G2, . . . , G4992 in FIG. 2 have a similar circuit configuration.

A driver IC includes a plurality of these pre-buffer circuits (e.g., G1 to G192), a plurality of latches (e.g. LT1 to LT192), a plurality of driving transistors (e.g., Tr1 to Tr192), a single inverter 51, and a single control voltage generator 60, as explained in connection with FIG. 4. The driver IC is connected by bonding wires, for example, to a plurality of LEDs (e.g., LD1 to LD192) in a LED array chip, each bonding wire linking the drain of a driving transistor to the anode of an LED.

The AND gate 41 in pre-buffer G1 is connected to the first power supply VD and ground (these power and ground connections are not explicitly shown in FIG. 9). The output signal Vin of the AND gate 41 accordingly swings between the VD and ground levels. The output terminal of the AND gate 41 is connected to the gate terminals of NMOS transistors M3, M5, and M12 and PMOS transistor M11 as described in the first embodiment. The AND gate 41 has two inputs: one is connected to the output terminal Q of latch LT1 and the other is connected to the output terminal of inverter 51.

In the level inverting circuit 44b, the source terminal of PMOS transistor M11 is connected to the first power supply VD and the source terminal of NMOS transistor M12 is connected to ground. The interconnected gate terminals of these two transistors form the input terminal of the level inverting circuit 44b, and their interconnected drain terminals form the output terminal.

In the level shifting inverter 46, the source terminal of PMOS transistor 42 is connected to the second power supply VDD and the source terminal of NMOS transistor 43 receives the control voltage Vcont from the control voltage generator 60. The interconnected gate terminals of these two transistors form the input terminal of the level shifting inverter 46, and their interconnected drain terminals form the output terminal.

The drain terminal voltages of PMOS transistor M1, M7, M8, M2, and 42 are indicated by Va, Vb, Vc, Vd, and Ve, respectively. The output of the AND gate 41 is the input signal Vin of the level shifting circuit 44a and level inverting circuit 44b. The first supply voltage VD is set at approximately half the second supply voltage VDD.

The control voltage generator 60 outputs the control voltage Vcont applied to the gates of the LED driving transistors Tr1, Tr2, . . . , Tr4992 (refer to FIG. 2) and controls the LED driving currents by making them mirror the current conducted by PMOS transistor 62, as described above. The gate length of PMOS transistor 62 in the control voltage generator 60 is equal to the gate lengths of the LED driving transistors Tr1, Tr2, . . . , Tr4992.

The reference voltage Vref applied to the inverting input terminal of the operational amplifier 61 is generated by a reference voltage generator (not shown). As described above, the control voltage generator 60 is configured as a feedback control circuit, in which the reference current Iref conducted by the resistor 63 and PMOS transistor 62 is determined by the reference voltage Vref and the resistance value Rref of the resistor 63, and remains constant despite any variations that may occur in the second supply voltage VDD.

The driving current values of the light-emitting diodes (e.g., LD1 to LD192) in a single LED array chip can be adjusted together since they are all proportional to the same reference current Iref. If the second supply voltage VDD varies, the control voltage Vcont tracks the variation so that the driving current supplied by the LED driving transistors (e.g., Tr1 to Tr192) remains unchanged. That is, the gate-source voltage of the driving transistors, which is the voltage difference between the control voltage Vcont and second power supply voltage VDD, is controlled to maintain a predetermined drain current value.

The LED driving current is also unaffected by variations in the value of the first supply voltage VD, which is supplied to the level shifting circuit 44a and level inverting circuit 44b in the pre-buffers, the AND gate 41, the inverter 51, the latches LT1, . . . , and the flip-flop circuits FF1, . . . constituting the shift register shown in FIG. 2.

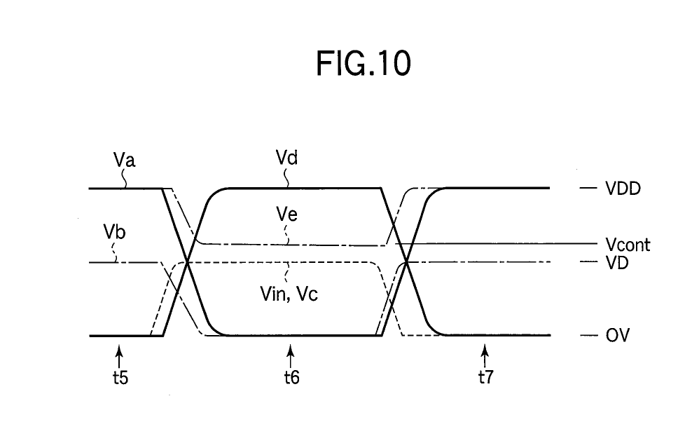

The operation of the LED driving circuit in FIG. 9 will be described with reference to the voltage waveform diagram in FIG. 10.

First, when the input signal Vin is at the low logic level as shown at time t5, the NMOS transistors M3, M5 that receive the input signal Vin directly at their gate terminals are turned off and the NMOS transistors M4, M6 that receive the inverted input signal from the level inverting circuit 44b at their gate terminals are turned on. In this state, PMOS transistor M1 is turned on and PMOS transistor M2 is turned off as described above, so the output signal Vd of the level shifting circuit 44a is at the ground voltage level (0 V).

Consequently, PMO$ transistor 42 is in the on state and NMOS transistor 43 is in the off state, so the output Ve of the level shifting inverter 46 is substantially equal to the second supply voltage VDD. Accordingly, there is no voltage difference between the gate and source terminals of LED driving transistor Tr1. LED driving transistor Tr1 is therefore in the cut-off state the light-emitting diode LD1 is turned off.

As explained in the first embodiment, the turned-on state of NMOS transistor M4 also causes PMOS transistor M7 to turn on and hence PMOS transistor M8 to turn off. The source-drain voltages Vds(M4) and Vds(M6) of NMOS transistors M4 and M6 are 0 V. Further, since the voltage Vb at the drain terminal of NMOS transistor M3 and the source terminal of NMOS transistor M5 is equal to the first supply voltage VD and the voltage Va at the drain terminal of NMOS transistor M5 is equal to the second supply voltage VDD, the source-drain voltages Vds(M3) and Vds(M5) of NMOS transistors M3 and M5 are both approximately equal to one-half the second supply voltage VDD (approximately equal to the first supply voltage VD).

When the input signal Vin changes to the high logic level at time t6, the on and off states of MOS transistors M1 to M8 all reverse. Accordingly, the output signal Vd of the level shifting circuit 44a becomes equal to the second supply voltage VDD, the source-drain voltages Vds(M3) and Vds(M5) of NMOS transistors M3 and M5 are 0 V, and the source-drain voltages Vds(M4) and Vds(M6) of NMOS transistors M4 and M6 are approximately one-half the second supply voltage VDD (approximately equal to the first supply voltage VD).

Since the output signal Vd of the level shifting circuit 44a is now substantially equal to the second supply voltage VDD, NMOS transistor 43 turns on and PMOS transistor 42 turns off in the level shifting inverter 46, so the output Ve of the level shifting inverter 46 is reduced to a voltage substantially equal to the control voltage Vcont. The difference between the control voltage Vcont and the second supply voltage VDD becomes the gate-source voltage of LED driving transistor Tr1. LED driving transistor Tr1 turns on and supplies a predetermined driving current to light-emitting diode LD1.

As described above, the LED driving circuit shown in FIG. 9 receives control signals having an amplitude equal to the first supply voltage VD from the latch LT1 and inverter 51. After passing through the AND gate 41 and level inverting circuit 44b, the control signal amplitude is still VD; that is, the signals Vin and S0 have 0 V as their low logic level and VD as their high logic level. The level shifting circuit 44a converts these control signals Vin and S0 to a signal Vd (S1) with a larger amplitude: its logic levels are 0 V and the second supply voltage VDD, which is the voltage used for driving the light-emitting diodes. The level shifting inverter 46 then converts this signal S1 to a signal S2 that swings between the second supply voltage VDD and the control voltage Vcont. These signal level conversions produce the voltages needed by the LED driving transistor Tr1 without subjecting any NMOS transistor to a gate-source or drain-source voltage significantly greater than the first supply voltage VD.

In particular, although the output voltage of the shifted signal S1 swings between ground and the second supply voltage VDD, the source-drain voltages of NMOS transistors M3 to M6 in the level shifting circuit 44a never exceed a voltage (VD or VDD−VD) approximately equal to half the second supply voltage VDD, regardless of the logic level of the input signal Vin.

Further, although the high output level of the level shifting inverter 46 is the second supply voltage VDD, its low output level is the control voltage Vcont. Therefore, it is not necessary to use high-voltage MOS transistors in the level shifting inverter 46; the drain-source voltages of transistors 42 and 43 are never greater than VDD−Vcont, which is always less than the second supply voltage VDD and is typically less than the first supply voltage VD.

As described above, the LED driving circuit shown in FIG. 9 permits the use of a comparatively high second supply voltage VDD to drive the light-emitting diodes and a comparatively low first supply voltage VD for logic and control circuitry, including in particular the shift register in each driver IC. Reducing the supply voltage of these circuits can drastically reduce the current and power consumed by the driver ICs.

High-voltage MOS transistors are not required in the logic and control circuits, since they operate at the comparatively low first supply voltage VD. Neither are high-voltage MOS transistors are required in the level-shifting circuits, so a driver IC incorporating the LED driving circuit in FIG. 9 can be reduced in size down to the fabrication limit of a fine-featured semiconductor fabrication process, thereby reducing the chip size and hence the chip cost.

### Third Embodiment

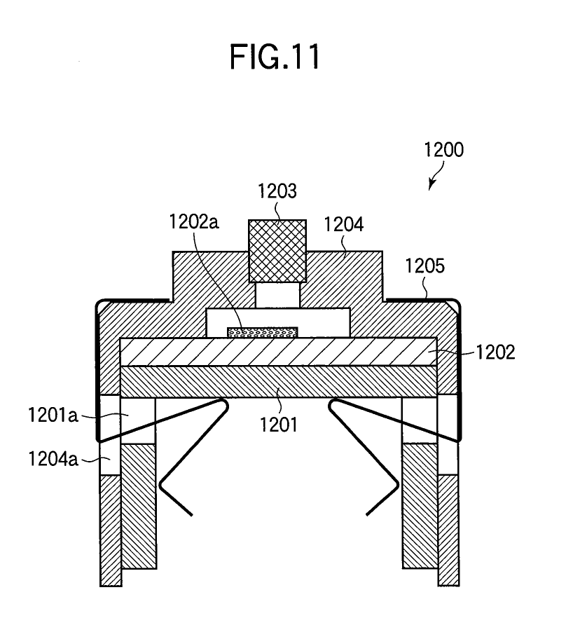

FIG. 11 is a sectional view of an LED print head 1200 illustrating a third embodiment of the invention.

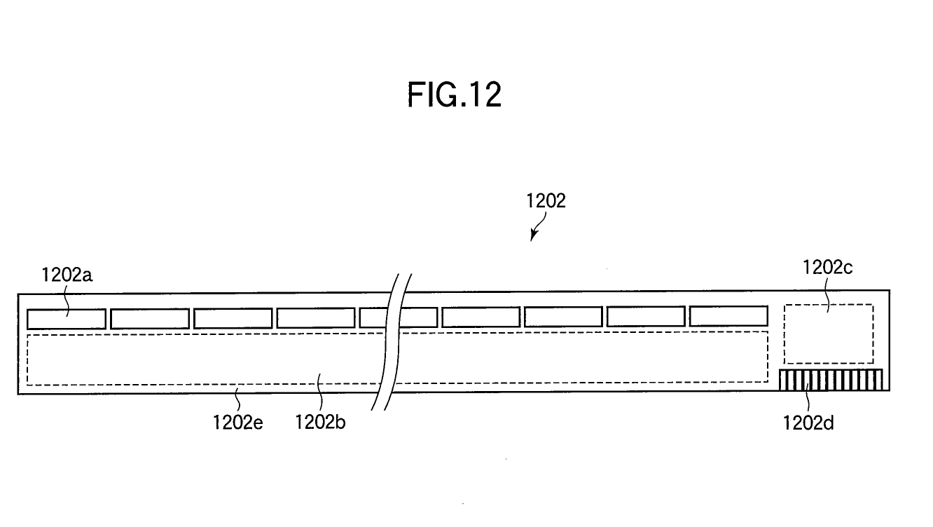

The LED print head 1200 includes a base member 1201 with an inverted U-shape. An LED unit 1202 is mounted on a base member 1201. The LED unit 1202 has, for example, twenty-six driver ICs including LED driving circuits as shown in the second embodiment (FIG. 9) mounted on a printed wiring board. FIG. 12 is a plan view showing an example of the LED unit 1202, where twenty-six LED array chips 1202a, each including 192 light-emitting diodes arranged in a line, are mounted in the longitudinal direction on the printed wiring board 1202e. The areas 1202b, 1202c indicated by the dotted lines on the printed wiring board 1202e are used for mounting and interconnecting the twenty-six driver IC chips and other electronic components (not shown). The twenty-six driver IC chips (not shown) are mounted facing the twenty-six LED array chips. The LED unit 1202 also includes a connector 1202d for receiving control signals and power, which are supplied from the outside.

Referring again to FIG. 11, a rod lens array 1203 is disposed above the light-emitting unit including the LED array chips 1202a in the LED unit 1202. The rod lens array 1203 is an optical element for collecting light emitted from the light-emitting unit. The rod lens array 1203 includes a large number of rod-shaped optical lenses aligned with the light-emitting unit and is held in a predetermined position by a lens holder 1204.

The lens holder 1204 encloses the base member 1201 and LED unit 1202 as shown in FIG. 11. The base member 1201, LED unit 1202, and lens holder 1204 are held together by a damper 1205 that extends through openings 1201a, 1204a in the base member 1201 and lens holder 1204. The light generated in the LED unit 1202 illuminates an external body such as a photosensitive drum through the rod lens array 1203. The LED print head 1200 is used as an exposure device in, for example, an electrophotographic printer or electrophotographic copier.

By using driver IC chips incorporating the LED driving circuit shown in the second embodiment (FIG. 9) in the LED unit 1202, the LED print head in FIG. 11 is able to provide high quality at a low cost.

### Fourth Embodiment

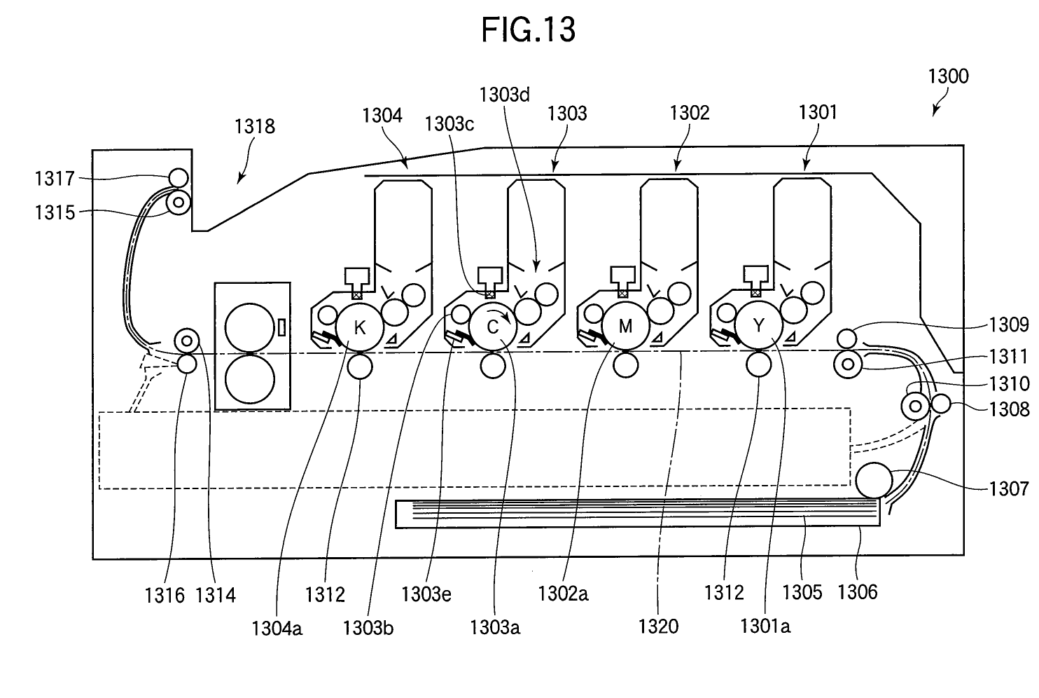

FIG. 13 shows an example of an LED color printer 1300 embodying the present invention.

The printer 1300 sends printing media such as paper through a yellow process unit 1301, a magenta process unit 1302, a cyan process unit 1303, and a black process unit 1304, which are mounted following one another in tandem fashion. These process units 1301, 1302, 1303, 1304 include respective photosensitive drums 1301a, 1302a, 1303a, 1304a, respective charging units that supply current to the photosensitive drums to charge the surfaces thereof, respective LED print heads that selectively illuminate the charged surfaces of the photosensitive drums to form electrostatic latent images, respective developing units that supply toner particles to the surfaces of the photosensitive drums to develop the electrostatic latent images, and respective cleaning units that remove remaining toner from the photosensitive drums after the developed images have been transferred to the printing media. The charging unit 1303b, LED print head 1303c, developing unit 1303d, and cleaning unit 1303e of the cyan process unit 1303 are identified in the drawing. The LED print heads have the structure described in the third embodiment.

The paper 1305 (or other media) is held as a stack of sheets in a cassette 1306. A hopping roller 1307 feeds the paper 1305 one sheet at a time toward a paired registration roller 1310 and pinch roller 1308. After passing between these rollers, the paper 1305 travels to another registration roller 1311 and pinch roller 1309, which feed the paper toward the yellow process unit 1301.

The paper 1305 passes through the process units 1301, 1302, 1303, 1304 in turn, traveling in each process unit between the photosensitive drum and a transfer roller 1312 made of, for example, semi-conductive rubber. The transfer roller 1312 is charged so as to create a potential difference between the photosensitive drum and the transfer roller 1312. The potential difference attracts the toner image from the photosensitive drum onto the paper 1305. A full-color image is built up on the paper 1305 in four stages, the yellow process unit 1301 using yellow toner to print a yellow image, the magenta process unit 1302 using magenta toner to print a magenta image, the cyan process unit 1303 using cyan toner to print a cyan image, the black process unit 1304 using black toner to print a black image.

From the black process unit 1304, the paper 1305 travels through a fuser 1313, in which a heat roller and back-up roller apply heat and pressure to fuse the transferred toner image onto the paper. A first delivery roller 1314 and pinch roller 1316 then feed the paper 1305 upward to a second delivery roller 1315 and pinch roller 1317, which deliver the printed paper onto a stacker 1318 at the top of the printer.

The photosensitive drum 1312 and various of the rollers are driven by motors and gears not shown in the drawing. The motors are controlled by a control unit (not shown) that, for example, drives registration roller 1310 and halts registration roller 1311 until the front edge of a sheet of paper 1305 rests flush against registration roller 1311, then drives registration roller 1311, thereby assuring that the paper 1305 is correctly aligned during its travel through the process units 1301, 1302, 1303, 1304.

The printer may include a double-sided printing unit as indicated by the dotted lines, in which case the paper can also be returned from delivery roller 1315 and pinch roller 1317 to registration roller 1310 and pinch roller 1308 and recycled through process units 1301, 1302, 1303, 1304 for printing on the other side.

By using the LED print heads of the third embodiment, in the printer 1300 shown in FIG. 13, the present invention enables high-quality printing to be obtained at a reasonable cost.

Although terms such as ‘upper’ and ‘lower’ have been used for convenience in the preceding descriptions, these terms do not limit the invented driving circuit and LED print head to use in any particular position or orientation.

The invention is not limited to electrophotographic printing or to the use of LEDs as the driven elements. The invention may also be usefully applied to electrophotographic printers using electroluminescent (EL) or organic light-emitting diode (O-LED) driven elements, to thermal printers using resistive heating elements as driven elements, or to display devices using arrays of image display elements.

The clamping circuit 44c in FIG. 5 may be replaced by a different clamping circuit. To mention just one possible alteration, the gate terminal of transistor M7 may receive the input signal Vin, and the gate terminal of transistor M8 may receive the inverted input signal.

The PMOS and NMOS transistors shown in the embodiments may be replaced by pnp and npn bipolar transistors.

The VD voltage need not be one-half of the VDD voltage. VD may be any voltage less than VDD.

Those skilled in the art will recognize that further variations are possible within the scope of the invention, which is defined in the appended claims.

What is claimed is:

1. A level shifting circuit for converting an input signal and an inverted input signal that vary in a complementary manner between a reference voltage and a first voltage higher than the reference voltage to a shifted signal that varies between the reference voltage and a second voltage higher than the first voltage, the level shifting circuit comprising:
a first node;
a second node;
a third node;
a fourth node for output of the shifted signal;
a clamping circuit for clamping the second node at the first voltage when the input signal is at the first voltage and clamping the first node at the first voltage when the input signal is at the reference voltage;
a first transistor of a first conductive type, having a first main terminal for receiving the second voltage, a second main terminal connected to the third node, and a control terminal connected to the fourth node;
a second transistor of the first conductive type, having a first main terminal for receiving the second voltage, a second main terminal connected to the fourth node, and a control terminal connected to the third node;
a third transistor of a second conductive type, having a first main terminal for receiving the reference voltage, a second main terminal connected to the first node, and a control terminal for receiving the input signal;
a fourth transistor of the second conductive type, having a first main terminal for receiving the reference voltage, a second main terminal connected to the second node, and a control terminal for receiving the inverted input signal;
a fifth transistor of the second conductive type, having a first main terminal connected to the first node, a second main terminal connected to the third node, and a control terminal for receiving the input signal; and
a sixth transistor of the second conductive type, having a first main terminal connected to the second node, a second main terminal connected to the fourth node, and a control terminal for receiving the inverted input signal;
each transistor of the first conductive type and each transistor of the second conductive type conducting current between its first main terminal and its second main terminal under control of its control terminal.

2. The level shifting circuit of claim 1, wherein the first and second transistors are p-channel metal-oxide-semiconductor transistors and the second through sixth transistors are n-channel metal-oxide-semiconductor transistors.

3. The level shifting circuit of claim 1, wherein the first and second transistors are pnp bipolar transistors and the second through sixth transistors are npn bipolar transistors.

4. The level shifting circuit of claim 1, wherein the clamping circuit comprises:
a seventh transistor of the first conductive type, having a first main terminal for receiving the second voltage, a second main terminal connected to the first node, and a control terminal connected to the second node; and
an eighth transistor of the first conductive type, having a first main terminal for receiving the second voltage, a second main terminal connected to the second node, and a control terminal connected to the first node.

5. The level shifting circuit of claim 4, wherein the seventh and eighth transistors are p-channel metal-oxide-semiconductor transistors.

6. The level shifting circuit of claim 4, wherein the seventh and eighth transistors are pnp bipolar transistors.

7. A driving device for individually driving a plurality of driven elements, the driving device comprising:
a plurality of pre-buffers corresponding to the plurality of driven elements, each one of the pre-buffers separately including a first level shifting circuit and a second level shifting circuit, the first level shifting circuit receiving an input signal that varies between a reference voltage and a first voltage and converting the input signal to a shifted signal that varies between the reference voltage and a second voltage, the second level shifting circuit converting the shifted signal generated by the first level shifting circuit to a reshifted signal that varies between a control voltage and the second voltage;
a plurality of driving transistors corresponding to the plurality of driven elements, for supplying driving current to the driven elements responsive to the reshifted signals output by respective ones of the pre-buffers; and
a control voltage generating circuit for generating the control voltage and supplying the control voltage to the second level shifting circuit in each one of the pre-buffers; wherein
each first level-shifting circuit separately comprises:
an inverter for inverting the input signal to create an inverted input signal that varies between the reference voltage and the first voltage;
a first node;
a second node;
a third node;
a fourth node for output of the shifted signal;
a clamping circuit for clamping the first node at the first voltage when the input signal is at the reference voltage and clamping the second node at the first voltage when the input signal is at the first voltage;
a first transistor of a first conductive type, having a first main terminal for receiving the second voltage, a second main terminal connected to the third node, and a control terminal connected to the fourth node;
a second transistor of the first conductive type, having a first main terminal for receiving the second voltage, a second main terminal connected to the fourth node, and a control terminal connected to the third node;
a third transistor of a second conductive type, having a first main terminal for receiving the reference voltage, a second main terminal connected to the first node, and a control terminal for receiving the input signal;
a fourth transistor of the second conductive type, having a first main terminal for receiving the reference voltage, a second main terminal connected to the second node, and a control terminal for receiving the inverted input signal;
a fifth transistor of the second conductive type, having a first main terminal connected to the first node, a second main terminal connected to the third node, and a control terminal for receiving the input signal; and
a sixth transistor of the second conductive type, having a first main terminal connected to the second node, a second main terminal connected to the fourth node, and a control terminal for receiving the inverted input signal;
each transistor of the first conductive type and each transistor of the second conductive type conducting current between its first main terminal and its second main terminal under control of its control terminal.

8. The driving device of claim 7, wherein the reference voltage is less than the control voltage and the first voltage, and the second voltage is greater than the control voltage and the first voltage.

9. The driving device of claim 7, wherein the reference voltage is a ground voltage and the first voltage is substantially one-half the second voltage.

10. The driving device of claim 7, wherein the driving transistors are p-channel metal-oxide-semiconductor transistors, each driving transistor having a first main terminal receiving the second voltage, a control terminal receiving the reshifted signal generated by the respective pre-buffer, and a second main terminal connected to the corresponding driven element.

11. A light-emitting diode print head comprising:
the driving device of claim 7;
an LED array including a plurality of light-emitting diodes driven by the driving device;
a supporting member for supporting the driving device and the LED array; and
a lens array for directing light emitted by the light-emitting diodes in the LED array.

12. An image forming apparatus comprising:
the LED print head of claim 11;
an image carrier having a surface selectively illuminated by the LED print head to form a latent electrostatic image;
a charger for charging the surface of the image carrier before the surface is illuminated by the LED print head; and
a developing unit for developing the latent image formed on the surface of the image carrier.
